(19) United States
(12) Patent Application Publication
(10) Pub. No.: US 2025/0359146 A1
(43) Pub. Date: Nov. 20, 2025

(54) HIGH-DENSITY STACKED TRANSISTORS WITH INDEPENDENT SOURCES OR DRAINS

(71) Applicant: Intel Corporation, Santa Clara, CA (US)

(72) Inventors: Abhishek A. Sharma, Portland, OR (US); Tahir Ghani, Portland, OR (US); Anand S. Murthy, Portland, OR (US); Wilfred Gomes, Portland, OR (US)

(73) Assignee: Intel Corporation, Santa Clara, CA (US)

(21) Appl. No.: 18/663,580

(22) Filed: May 14, 2024

(51) Int. Cl. H01L 29/786; H01L 27/06; H01L 27/088; H01L 29/06; H01L 29/423; H01L 29/775

(52) U.S. Cl. CPC H10D 30/6713; H10D 30/43; H10D 30/6735; H10D 30/6757; H10D 62/121; H10D 84/83; H10D 88/00

(57) ABSTRACT

A vertical stack of three-dimensional transistors, such as nanoribbon-based transistors, includes a stack of nanoribbons with independent sources or drained coupled to different nanoribbons or subsets of nanoribbons in the stack. In previous nanoribbon transistors, source/drain regions join the ends of a stack of nanoribbons together, thus electrically shorting the source ends together and the drain ends together. To achieve a stack of semiconductor regions with independent sources or drains, adjacent nanoribbons in the stack may be set at different distances apart, or the source side and drain side may be deposited in separate deposition processes.

### BACKGROUND

Non-planar transistors are three-dimensional electronic devices that deviate from a traditional flat transistor design. Compared to planar transistors, non-planar transistors can provide improved control over current flow, reduced leakage, and enhanced performance, making it a key technology for smaller, faster, and more energy-efficient electronic devices. Examples of non-planar transistors include fin-shaped field-effect transistors, referred to as FinFETs, and gate-all-around (GAA) transistors. GAA transistors, also referred to as surrounding-gate transistors, have a gate material that surrounds a channel region on all sides. GAA transistors may be nanoribbon-based or nanowire-based.

Non-planar transistors may use a monocrystalline material, such as monocrystalline silicon, to form semiconductor channels. For example, alternating layers of different monocrystalline materials (e.g., silicon and germanium) can be grown in layers. One of the materials is a sacrificial material that is removed during processing to form stacks of the channel material. A gate stack that may include one or more gate electrode materials and a gate dielectric is provided around a central portion of the semiconductor channel. A source region and a drain region are provided on the opposite ends of the semiconductor channel, forming, respectively, a source and a drain of the transistor. The source and drain regions are insulated from the gate stack, so that the voltages at the three terminals (gate, source, and drain) may be separately controlled.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a nanoribbon-based transistor showing the source, gate, and drain.

FIG. 1B is a cross-section of the nanoribbon-based transistor through the plane AA′ in FIG. 1A.

FIG. 2 is an electrical circuit diagram of the nanoribbon-based transistor shown in FIG. 1.

FIG. 3 is an electrical circuit diagram of a stack of nanoribbon-based transistors with three independent source regions, according to some embodiments of the present disclosure.

FIG. 4 is a cross-section of a first example implementation of FIG. 3 with smaller epitaxial deposits on the source side, according to some embodiments of the present disclosure.

FIG. 5 is a cross-section of a second example implementation of FIG. 3 with variation in materials between different transistors, according to some embodiments of the present disclosure.

FIG. 6 is an electrical circuit diagram of a stack of nanoribbon-based transistors with two independent drain regions, according to some embodiments of the present disclosure.

FIG. 7 is a cross-section of a first example implementation of FIG. 6 with unequally spaced semiconductor regions, according to some embodiments of the present disclosure.

FIG. 8 is a cross-section of a second example implementation of FIG. 6 with different materials in a single transistor, according to some embodiments of the present disclosure.

FIG. 9 is an electrical circuit diagram of a stack of nanoribbon-based transistors with two independent drain regions and two independent source regions, according to some embodiments of the present disclosure.

FIG. 10 is a cross-section of a first example implementation of FIG. 9 with unequally spaced semiconductor regions, according to some embodiments of the present disclosure.

FIG. 11 is a cross-section of a second example implementation of FIG. 9 with different materials in different transistors, according to some embodiments of the present disclosure.

FIG. 12 is an electrical circuit diagram of a stack of nanoribbon-based transistors with two independent drain regions and two independent gate stacks, according to some embodiments of the present disclosure.

FIG. 13 is a cross-section of an example implementation of FIG. 12, according to some embodiments of the present disclosure.

FIG. 14 is a top view of a wafer and dies that include one or more stacked transistors with independent sources or drains in accordance with any of the embodiments disclosed herein.

FIG. 15 is a cross-sectional side view of an IC device that may include one or more stacked transistors with independent sources or drains in accordance with any of the embodiments disclosed herein.

FIG. 16 is a cross-sectional side view of an IC device assembly that may include one or more stacked transistors with independent sources or drains in accordance with any of the embodiments disclosed herein.

FIG. 17 is a block diagram of an example computing device that may include one or more stacked transistors with independent sources or drains in accordance with any of the embodiments disclosed herein.

FIG. 18 is a block diagram of an example processing device that includes an IC device with one or more stacked transistors with independent sources or drains in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Transistors typically include a gate stack coupled to a semiconductor channel, which may be a nanoribbon or a stack of nanoribbons. A gate stack often includes a gate electrode and a gate dielectric, with the gate dielectric formed between the gate electrode and the channel material. In a GAA transistor, the gate dielectric is formed around each semiconductor region (e.g., each nanoribbon), and the gate electrode is formed over and around the gate dielectric, including in spaces between adjacent semiconductor regions. In some implementations of GAA transistors, the gate dielectric is omitted. A source region is formed at one end of the semiconductor regions, and a drain region is formed at the opposite end of the semiconductor regions, thus realizing a three-terminal device.

Described herein are IC devices that include vertically stacked non-planar or three-dimensional transistors, such as nanoribbon-based transistors. In previous GAA transistors, the gate electrode wraps around all of the semiconductor regions and spans the areas between adjacent semiconductor regions, thus electrically coupling the centers of the semiconductor regions. In addition, source and drain regions extended across the respective ends of the semiconductor regions in the stack, shorting together the nanoribbons at either end to form a single source region and a single drain region.

As disclosed herein, a vertical stack of two or more independent transistors may be formed using a stack of semiconductor regions, where each transistor has an independent source region or drain region. For example, varying the spacing between the semiconductor regions, or using two or more sacrificial materials when forming the stack of semiconductor materials, can enable creation of independent source or drain regions that are physically and electrically isolated from one another. The independent source or drain regions may be separately controlled, e.g., through independent contacts to a metallization stack. In some embodiments, the stack of independent transistors may also have independent gates that are physically and electrically separated from one another.

In some embodiments, different transistors may have different strengths, e.g., different numbers of semiconductor regions. In previous transistor architectures, semiconductor regions (e.g., semiconductor fins) were typically formed in even numbers, so that transistors formed around multiple channel regions had an even number of channel regions, e.g., two fins, four fins, or six fins. In the GAA transistors disclosed herein, any number of semiconductor regions may be combined in a transistor, e.g., one semiconductor region, two semiconductor regions, three semiconductor regions, four semiconductor regions, five semiconductor regions, etc. In a given vertical stack, different transistors may have different number of semiconductor regions, e.g., a one-nanoribbon transistor may be stacked over a two-nanoribbon transistor, or a three-nanoribbon transistor may be stacked over a one-nanoribbon transistor. The different strength transistors may be used for different functions, e.g., a relatively “strong” transistor with more semiconductor regions may be used as a pull-up or pull-down transistor, while a relatively “weak” transistor with fewer semiconductor regions may be used as a logic or data transistor. In some embodiments, at least one transistor in the stack may include an odd number of semiconductor regions (e.g., one, three, five, etc.). For example, a transistor with an odd number of semiconductor regions may be below a transistor that includes a transistor with an even number of semiconductor regions, or above a transistor that includes a transistor with an even number of semiconductor regions.

Different transistors in the stack may be different from one another in other ways. For example, different transistors may include different channel materials and/or different source/drain materials. In some embodiments, a single transistor may include heterogenous materials, e.g., one transistor may include different nanoribbons of different semiconductor materials.

Nanoribbons are often small structures, with a low amount of current passing through each individual nanoribbon. In many nanoribbon-based transistors, multiple nanoribbons are used together in a single transistor to provide adequate current flow through the transistor, as noted above. In general, when transistors operate at lower temperatures, they have improved performance. For example, electron mobility in semiconductors improves at lower temperatures, which can lead to increased drive currents across semiconductor regions, e.g., across transistors or individual nanoribbons. In addition, transistors at lower temperatures generally experience lower leakage than transistors operating at higher temperatures. These factors can allow smaller transistors when the IC device is operating at a lower temperature. In addition, the electron mobility in a single nanoribbon may be enhanced through selection of a high-mobility channel material. In some cases, e.g., in low-temperature applications where the drive current through an individual nanoribbon is greater, transistors can be built around individual nanoribbons in a stack, or a portion of nanoribbons in a stack (e.g., two or three nanoribbons), rather than around full stacks of nanoribbons.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

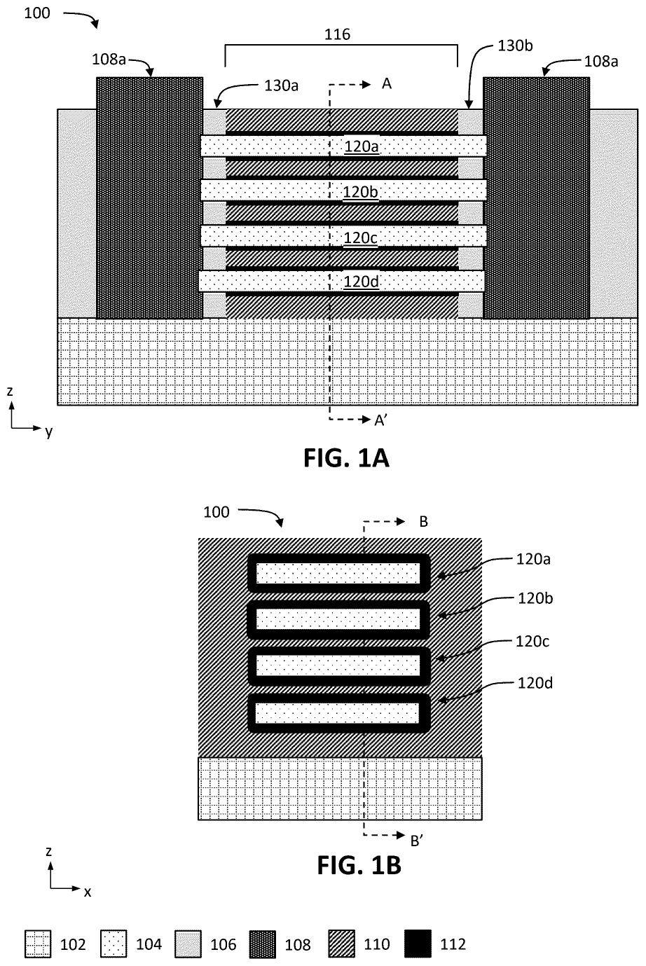

For convenience, if a collection of drawings designated with different letters are present, e.g., FIGS. 1A-1B, such a collection may be referred to herein without the letters, e.g., as “FIG. 1.”

### Example Nanoribbon Transistor

FIGS. 1A-1B illustrate an example architecture of a nanoribbon-based transistor. FIG. 1A is a cross-section across a transistor 100 showing the source, gate, and drain. FIG. 1B is a cross-section across the gate regions of the transistor 100. FIG. 1B is a cross-section through the plane AA′ in FIG. 1A, and FIG. 1A is a cross-section through the plane BB′ in FIG. 1B. The nanoribbon-based transistor 100 illustrates certain structures and materials that may be used in the vertically stacked transistors with independent sources or drains discussed further below.

A number of elements referred to in the description of FIGS. 1-13, and with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) region 108, a gate electrode 110, and a gate dielectric 112.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

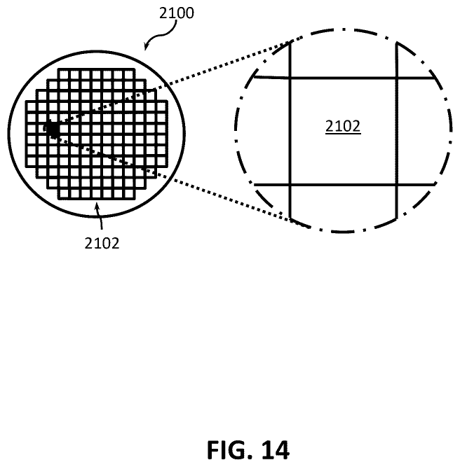

In general, implementations of the present disclosure may be formed or carried out on a support structure, e.g., the support structure 102 illustrated in FIG. 1. The support structure 102 may be, e.g., a substrate, a die, a wafer or a chip. For example, the support structure may be the wafer 2100 of FIG. 14, discussed below, and may be, or be included in, a die, e.g., the singulated die 2102 of FIG. 14, discussed below. The support structure 102 extends along the x-y plane in the coordinate system shown in FIG. 1. In some embodiments, a support structure 102 may be used during a fabrication process and later removed. For example, a top side of the transistor 100 may be attached to a second support structure (e.g., a second one of the support structures 102, which may be referred to as a carrier structure), and the support structure 102 over which the transistor 100 is formed may be removed to expose the back side of the transistor 100.

In some embodiments, a support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In FIGS. 1A and 1B, a transistor 100 is formed over a support structure 102. The transistor 100 includes a channel material 104 formed into four nanoribbons stacked on top of each other. In other examples, the transistor 100 may include more or fewer nanoribbons, e.g., one, two, three, five, six or more nanoribbons. The channel material 104 may be a semiconductor, such as silicon or other semiconductor materials described herein.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIGS. 1A and 1B, i.e., a different distance from the support structure 102, where the nanoribbon 120a is the greatest distance from the support structure 102, and the nanoribbon 120d is the smallest distance from the support structure 102. S/D regions 108a and 108b are formed at either end of the nanoribbon channels 120, as illustrated in FIG. 1A.

In general, to form nanoribbon channels such as the nanoribbon channels 120, alternating layers of the channel material 104 and a sacrificial material are deposited over the support structure 102. The sacrificial material is removed from the stack and replaced with other material, e.g., material for forming a gate stack 116, so the sacrificial material is not shown in FIG. 1. The channel material 104 and sacrificial material include different materials. In one example, the channel material 104 is silicon, while the sacrificial material includes silicon and germanium. The sacrificial material may be chosen to have a similar crystal structure to the channel material 104, so that monocrystalline layers of the channel material 104 (or substantially monocrystalline layers, e.g., with a grain size of at least 5 nanometers, at least 20 nanometers, at least 50 nanometers, or at least 100 nanometers) and monocrystalline layers of the sacrificial material (or substantially monocrystalline layers) may be formed over each other. In different embodiments, the channel material 104 and/or the sacrificial material may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide III compound, where arsenic III is in combination with another element such as boron, aluminum, gallium, or indium), or any group III-V material (i.e., materials from groups III and V of the periodic system of elements).

More generally, the channel material 104 may be composed of semiconductor material systems including, for example, N-type or P-type materials systems. The channel material 104 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 104 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some cases, multiple channel materials may be included within an IC device. For example, an IC device may include both N-type metal-oxide-semiconductor (NMOS) transistors and P-type MOS (PMOS) transistors, e.g., alternating rows of NMOS and PMOS transistors. NMOS and PMOS logic can use different groups of channel material 104, e.g., silicon may be used to form an N-type semiconductor channel, while silicon germanium may be used to form a P-type semiconductor channel. In some cases, a single channel material 104 is used (e.g., silicon), and different portions (e.g., channel material to form different transistors) may include different dopants, e.g., N-type dopants for NMOS transistors and P-type dopants for PMOS transistors.

The S/D regions 108 may be formed from one or more layers of doped semiconductors, metals, metal alloys, or other materials. For example, the S/D regions 108 may include a doped semiconductor, such as silicon or another semiconductor doped with an N-type dopant or a P-type dopant. The S/D regions 108 may include multiple layers with different levels of conductivity, e.g., a doped semiconductor followed by a more highly doped semiconductor, or a semiconductor followed by metal.

A central portion of each of the nanoribbon channels 120 is surrounded by a gate stack 116, which in this example, includes a gate electrode 110 and gate dielectric 112. Nanoribbon transistors often include a gate dielectric that surrounds the nanoribbon channels 120, and a gate electrode that surrounds the gate dielectric. While not specifically shown, in some cases, the gate dielectric 112 around each nanoribbon channel 120 includes multiple layers, e.g., an oxide layer and a high-k dielectric layer. The oxide layer may be grown directly on the nanoribbon channels 120, and the high-k dielectric may surround the oxide. The oxide may include oxygen in combination with the channel material 104. For example, if the nanoribbon channels are formed from silicon, the gate dielectric 112 may include a layer of silicon oxide. The high-k dielectric may be formed over the oxide. The gate electrode 110 surrounds the gate dielectric 112, e.g., the high-k dielectric (if included). In this example, the gate electrode 110 is above and below the nanoribbon stack, and between adjacent nanoribbons 120.

The gate electrode 110 includes a conductive material, such as a metal. The gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). The gate electrode 110 may include a stack of two or more metal layers, where one or more metal layers are work function metal layers and at least one metal layer is a fill metal layer.

The gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The gate dielectric 112 may have a thickness between about 0.5 nanometers and 3 nanometers, including all values and ranges therein, e.g., between about 1 and 3 nanometers, or between about 1 and 2 nanometers.

Regions of the transistor 100 outside of the nanoribbons 120, gate stack 116, and S/D regions 108 are filled in with a dielectric material 106. In the region between the gate stack 116 and the S/D region 108a, the dielectric material 106 forms a first series of cavity spacers 130a; a second series of cavity spacers 130b is between the gate stack 116 and the S/D region 108b. Cavity spacers 130, also referred to as “dimple spacers” or “inner spacers,” provide electrical isolation between the S/D regions 108 formed at the ends of the nanoribbons and the gate electrode 110 deposited around the nanoribbons 120.

FIG. 1 illustrates a single nanoribbon transistor 100. In IC devices, many similar or identical transistors are arranged within a transistor layer. The dielectric material 106 and/or different dielectric materials may provide isolation between different transistors, or between other conductive materials in or near the transistor layer.

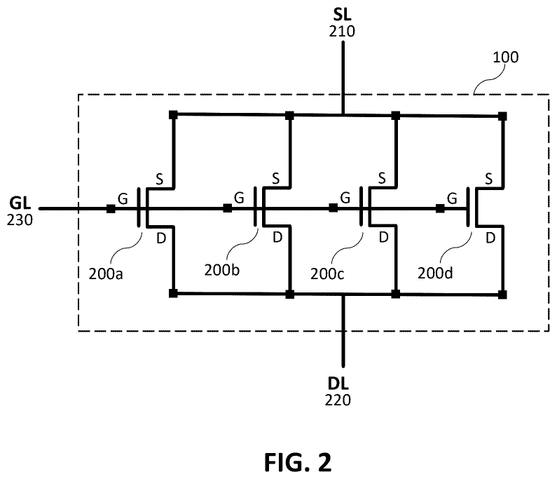

FIG. 2 is an electrical circuit diagram of the nanoribbon-based transistor 100 shown in FIG. 1. The transistor 100 includes four nanoribbons 120a, 120b, 120c, and 120d, each corresponding to a transistor 200a, 200b, 200c, and 200d in FIG. 2. Each transistor 200 has a gate terminal, a source terminal, and a drain terminal, indicated in the example of FIG. 2 as terminals G, S, and D, respectively. In the following, the terms “terminal” and “electrode” may be used interchangeably. Furthermore, for S/D terminals, the terms “terminal” and “region” may be used interchangeably.

As shown in FIG. 2, in the transistor 100, the gate terminals of the four transistor 200a-200d are coupled together (e.g., by the electrode 110 shown in FIG. 1) and connected to a gate line (GL) 230. One of the S/D terminals (in this example, the source terminal, S) of each transistor 200 are coupled together (e.g., at the S/D region 108a of FIG. 1) and then coupled to a source line (SL) 210. The other one of the S/D terminals (in this example, the drain terminal, D) of each transistor 200 are coupled together (e.g., at the S/D region 108b of FIG. 1) and then coupled to a drain line (DL) 220. Coupling together the gates, sources, and drains of the four transistors 200 effectively forms a single transistor 100. As is known in the art, the SL, GL, and DL may be used together to control the transistor 100.

Each of the SL 210, the DL 220, and the GL 230 may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

### Example Nanoribbon Transistors with Independent Source Regions

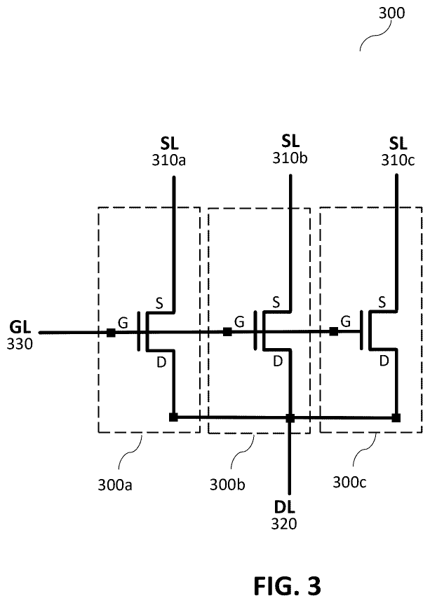

FIG. 3 is an electrical circuit diagram of a stack of nanoribbon-based transistors with three independent source regions, according to some embodiments of the present disclosure. FIG. 3 includes three transistors 300a, 300b, and 300c, each formed around a respective semiconductor region, such as a nanoribbon. Each transistor 300 includes a G, S, and D, as described with respect to FIG. 2.

The gate terminals of the three transistor 300a-300c are coupled together and connected to a GL 330. One of the S/D terminals (in this example, the drain terminal, D) of each transistor 300 are coupled together (e.g., in a S/D region) and then coupled to a DL 320. The other ones of the S/D terminals (in this example, the source terminal, S) of each transistor 300 are independent from each other and are coupled to three independent SLs 310. The source terminal of transistor 300a is coupled to the SL 310a, the source terminal of transistor 300b is coupled to the SL 310b, and the source terminal of transistor 300c is coupled to the SL 310c. By leaving the source terminals and SLs 310 separate from each other, the stack of semiconductor regions can be used to form three independent transistors.

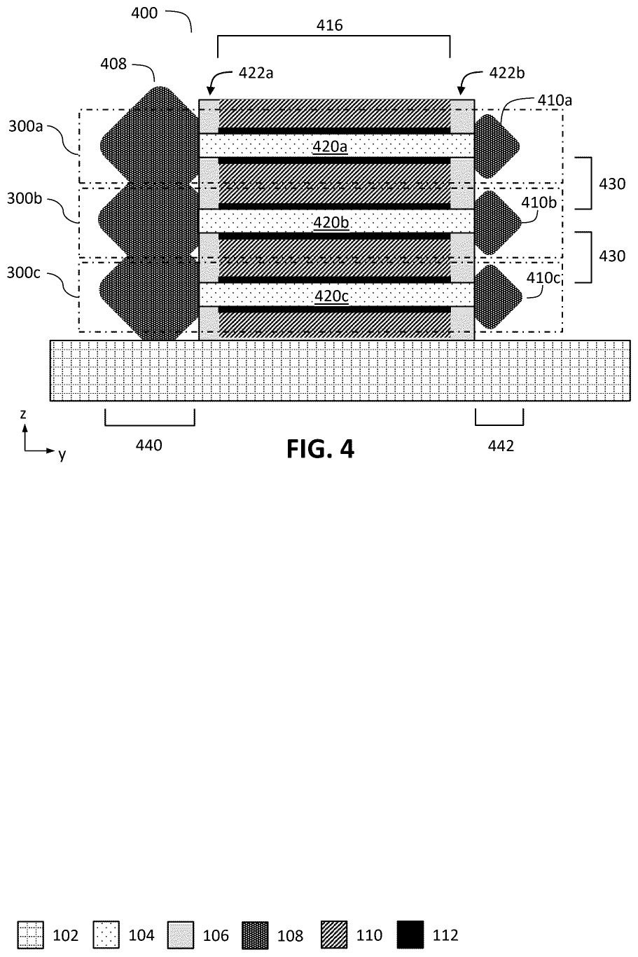

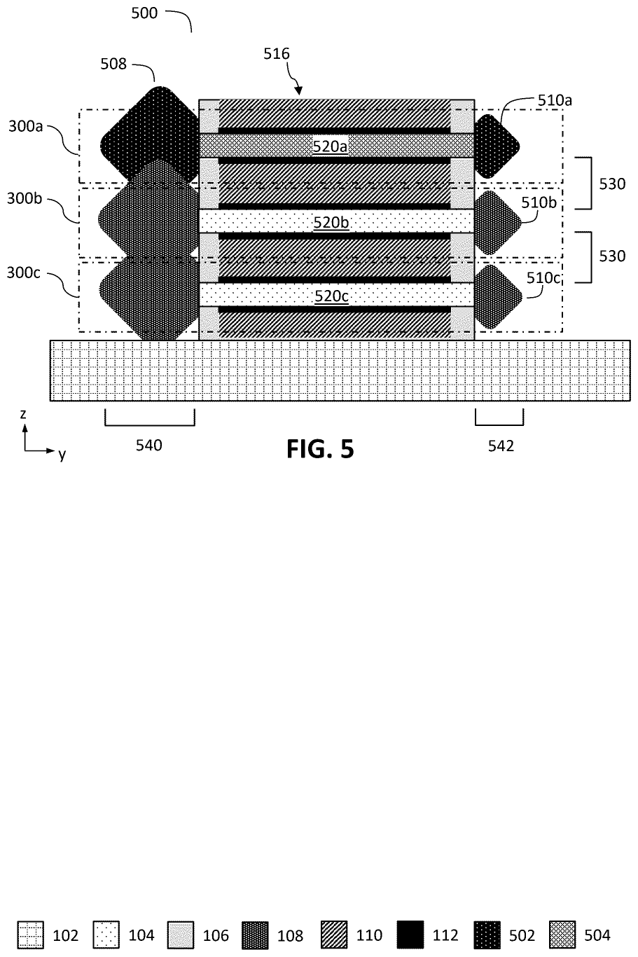

The transistors 300a-300c illustrated in FIG. 3 may be realized in several different ways. Two example implementations are shown in FIGS. 4 and 5, and additional variations are described. While three transistors 300a-300c are illustrated in FIG. 3, and stacks of three transistors illustrated in FIGS. 4 and 5, fewer or additional transistors (e.g., two, four, five, six, or more transistors) formed around fewer or additional semiconductor regions in a stack may be included; the additional transistors may be connected in a similar manner to the transistors 300 in FIG. 3. Furthermore, while one side of the transistors 300 is represented and described as a source and the other side represented and described as a drain, as noted above, designations of source and drain are often interchangeable, and the source and drain regions may be reversed (i.e., so that the sources are coupled together, and the drains are independent).

FIG. 4 is a cross-section of a first example implementation of a stack 400 of nanoribbon-based transistors. FIG. 4 depicts an example with smaller epitaxial deposits on the source side. In FIG. 4, a stack of three semiconductor regions 420a, 420b, and 420c are over a support structure 102, which may be the support structure 102 described with respect to FIG. 1. The first transistor 300a is formed around the uppermost semiconductor region 420a, the second transistor 300b is formed around the middle semiconductor region 420b, and the third transistor 300c is formed around the lowest semiconductor region 420c.

The semiconductor regions 420, also referred to herein as nanoribbons 420, include the channel material 104, which may be the channel material 104 described with respect to FIG. 1. The nanoribbons 420a, 420b, and 420c are referred to collectively as nanoribbons 420 or individually as a nanoribbon 420. The nanoribbons 420 may be any three-dimensional semiconductor structures around which the memory cells described herein may be formed, including, for example, nanowires with a square or circular cross-section, or nanosheets with a wider rectangular cross section. The term nanosheet is sometimes used to highlight the relative breadth and thinness of a particular nanoribbon structure. For example, the term nanosheet may indicate that a structure has a small height (in the z-direction in the example coordinate system) and a broader width (into the page in FIG. 4, i.e., in the x-direction in the coordinate system shown) compared to other nanostructures, like nanowires. In other embodiments, the nanoribbons 420 may have cross-sections that are squares with rounded corners, rectangles with rounded corners, ovals, or other shapes. In some embodiments, the nanoribbons 420 are oriented in a perpendicular direction to that shown, with a height (in the z-direction) greater than the width (in the x-direction); in such embodiments, the nanoribbons 420 may be referred to as fins. In still other embodiments, the nanoribbons 420 are coupled on one side (e.g., on the right side in the orientation shown in FIG. 4) to a dielectric fin, and another set of nanoribbons extend from the opposite side of the dielectric fin, thus forming a forksheet arrangement.

The nanoribbons 420 each have an elongated structure that extends over the support structure 102. Each nanoribbon 420 extends primarily in the y-direction in the coordinate system used in the figures, and thus the nanoribbon structures are considered to be elongated in this direction. The direction in which the nanoribbons 420 extend is parallel to the support structure 102; this direction in which the nanoribbons 420 extend is also parallel to the other nanoribbons in the stack. While a stack of three nanoribbons 420a-420c is shown, forming the stack of three transistors 300a-300c, in other embodiments, the stack of nanoribbons may include more or fewer nanoribbons, e.g., two, four, five, six or more nanoribbons 420. Furthermore, in other embodiments, a different number of transistors with a different number of independent sources or drains (e.g., two transistors, four transistors, five transistors, etc.) may be formed.

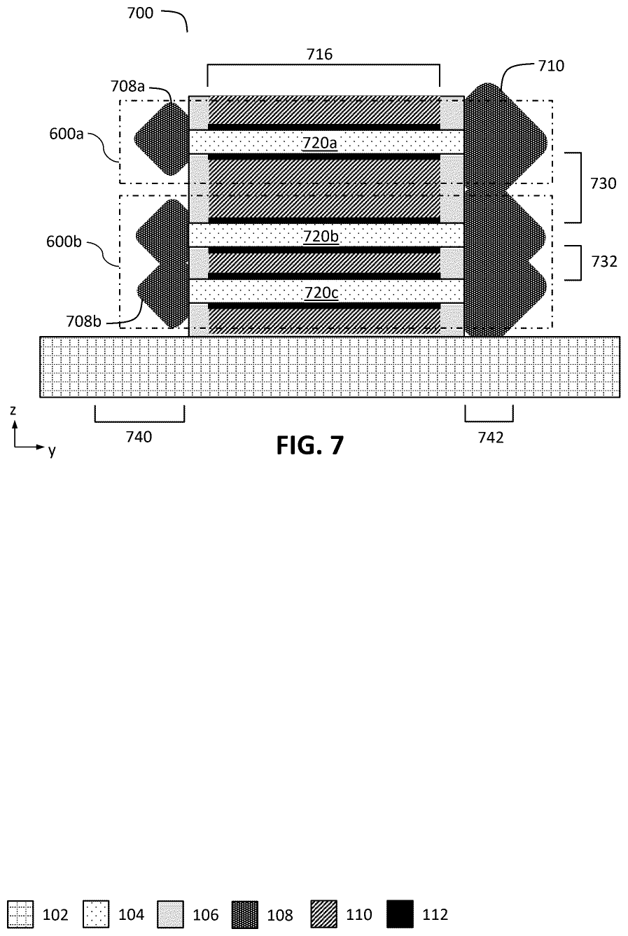

Each nanoribbon 420 is at a different height in the z-direction in the coordinate system shown, i.e., a different distance from the support structure 102, where the nanoribbon 420a is the greatest distance from the support structure 102, and the nanoribbon 420c is the smallest distance from the support structure 102. In this example, the nanoribbons 420 are evenly spaced; a distance 430 is between the nanoribbons 420a and 420b, and the same distance 430 or substantially the same distance is between the nanoribbons 420b and 420c. For example, a first distance between the nanoribbons 420a and 420b may be within 5%, 10%, 20%, 25%, 30% of a second distance between the nanoribbons 420b and 420c, or within some other tolerance. While the distance 430 is depicted as being measured from the edges of the nanoribbons, the pitches (i.e., center-to-center distances) may be compared, and may be within any of the tolerances noted above, or some other tolerance. In other embodiments, nanoribbons may be unevenly spaced, e.g., as shown in FIGS. 7-8, 10-11, and 13.

Central portions of the nanoribbons 420a-420c are surrounded by a gate stack 416, which like the gate stack 116, includes a gate electrode 110 and gate dielectric 112 described with respect to FIG. 1. The gate dielectric 112 surrounds the nanoribbons 420, and the gate electrode 110 surrounds the gate dielectric 112. The gate dielectric 112 and gate electrode 110 span the height 430 between pairs of adjacent nanoribbons 420, so that the gate electrode 110 electrically couples the nanoribbons 420a, 420b, and 420c. Two regions 422a and 422b of the dielectric material 106 are on either side of the gate stack 416, forming spacers similar to the cavity spacers 130 shown in FIG. 1 and described above. Other regions of the device outside of the nanoribbons 420, gate stack 416, and S/D regions 408 and 410 (described below) may also be filled in with a dielectric material, e.g., the dielectric material 106.

A first S/D region 408 is at one end of the nanoribbons 420, e.g., the drain side of the nanoribbons 420. The first S/D regions 408 spans the height of the stack of nanoribbons 420 and is physically and electrically coupled to each of the nanoribbons 420a, 420b, and 420c, thus electrically coupling the left or drain ends of the nanoribbons 420a, 420b, and 420c together. The first S/D region 408 may be similar to the first S/D region 108 of FIG. 1.

On the opposite end of the nanoribbons 420, an independent S/D region 410a, 410b, or 410c is coupled to each of the nanoribbons 420a, 420b, or 420c. The S/D regions 410a, 410b, and 410c coupled to the different nanoribbons 420a, 420b, or 420c are physically and electrically isolated from each other. Thus, an individual nanoribbon (e.g., nanoribbon 420a) may have its own independent source (e.g., the S/D region 410a), which is independent from the other S/D regions 410b and 410c.

The S/D regions 408 and 410 may include the S/D materials 108 described with respect to FIG. 1. In the illustration of FIG. 4, the S/D regions 408 and 410 may be epitaxially grown. An epitaxial growth process can result in a generally diamond-shaped structure, as shown in FIG. 4, due to the crystallographic orientation of the underlying semiconductor material (e.g., the nanoribbons 420) and/or the growth process itself. Specifically, during an epitaxial deposition process, the growth tends to follow the crystal structure of the underlying structures, with a higher growth rate along certain crystallographic directions compared to others.

The S/D region 408 has a width 440 that is greater than a width 442 of the S/D regions 410. To obtain the single S/D region 408 at one end of the nanoribbons 420 and the independent S/D regions 410 on the opposite ends of the nanoribbons 420, at least part of the epitaxial growth of the S/D region 408 may be grown while the source ends of the nanoribbons 420 or epitaxial regions 410 are blocked. For example, a first epitaxial growth process can be performed over both ends of the nanoribbons 420. After the first epitaxial growth process, the S/D regions 410 may have the appearance shown in FIG. 4, and a mirror image of the S/D regions 410 may be formed over the opposite ends of the nanoribbons 420. The S/D regions 410 may then be blocked or masked. A second epitaxial growth process may then be performed to expand the size of the S/D regions on the left side of the nanoribbons 420, so that the S/D regions increase in width and height. During the second epitaxial growth process, the S/D regions extending outward from the left side of the nanoribbons 420 grow together, forming the single S/D region 408 shown in FIG. 4.

In another example, the S/D regions 408 and 410 may be formed in two separate processes. For example, the left side of the nanoribbons 420 may be blocked or masked during growth of the S/D regions 410, and then the S/D regions 410 are blocked or masked during growth of the S/D region 408. Alternatively, the S/D region 408 may be grown before the S/D regions 410.

In FIG. 4, the channel material 104 is included in the three nanoribbons 420a, 420b, and 420c, and the S/D material 108 is included in the S/D regions 408 and 410. In other embodiments, different materials may be included at different rows in the nanoribbon stack.

FIG. 5 is a cross-section of a second example implementation of FIG. 3 with variation in materials between different transistors, according to some embodiments of the present disclosure. FIG. 5 includes a stack 500 of the three transistors 300a, 300b, and 300c, formed around three nanoribbons 520a, 520b, and 520c. The nanoribbons 520 are similar to the nanoribbons 420 of FIG. 4, except that one nanoribbon, here 520a, has a different channel material 504 from the channel material 104 of the other nanoribbons 520b and 520c. The S/D regions 508 and 510 are similar to the S/D regions 408 and 410 of FIG. 4, except that a different S/D material 502 is coupled to the nanoribbon 520a. The S/D region 508 has a width 540, which is similar to the width 440, and the S/D regions 510 have a width 542, which is similar to the width 442. A gate stack 516, similar to the gate stack 416 of FIG. 4, surrounds the nanoribbons 520.

The different channel materials 104 and 504 may include different elements (e.g., the channel material 104 includes silicon, and the channel material 504 includes germanium, or one of the thin film semiconductors described above), different concentrations of elements (e.g., the channel materials 104 and 504 include different relative concentrations of silicon and germanium), and/or different material structures (e.g., the channel material 104 is monocrystalline, while the channel material 504 is polymorphous or amorphous). While the nanoribbons 520a, 520b, and 520c are depicted as having a same thickness in the z-direction, nanoribbons formed from the different channel materials 104 and 504 may have different thicknesses. While two different channel materials are shown in FIG. 5, in other examples, three or more different channel materials may be included in different semiconductor regions. In the example of FIG. 5, the nanoribbons 520 are evenly spaced by a distance 530.

In this example, the upper portion of the S/D region 508 coupled to the left end of the nanoribbon 520a, and the S/D region 510a coupled to the right end of the nanoribbon 520a, are formed from a S/D material 502 that is different from the S/D material 108. The upper portion of the S/D region 508 that includes the S/D material 502 may be grown in a separate process (e.g., a different epitaxial deposition process) from the lower portion of the S/D region 108 that includes the S/D material 108. Likewise, the S/D region 510a may be grown in a separate process (e.g., a different epitaxial deposition process) from the S/D regions 510b and 510c. The S/D material 502 may be a material suited for growing on the channel material 504. The S/D material 502 may be selected for suitable physical and/or electrical properties with respect to the channel material 504. In the S/D region 508, the respective portions of the S/D material 502 and the S/D material 108 are physically and electrically coupled, so that charge may pass from the S/D material 502 to the S/D material 108 or vice versa.

Using different channel materials and/or different S/D materials in different transistors can result in a stack of transistors where transistors within the stack have different electrical properties. For example, different channel materials may provide transistors with different threshold voltages.

### Example Nanoribbon Transistors with Unequally Spaced Nanoribbons and Independent Drains

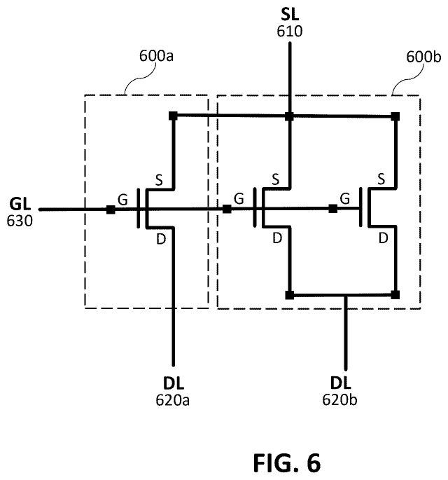

FIG. 6 is an electrical circuit diagram of a stack of nanoribbon-based transistors with two independent drain regions, according to some embodiments of the present disclosure. FIG. 6 includes two transistors 600a and 600b, where transistor 600a is formed around a single semiconductor region, such as a nanoribbon, and transistor 600b is formed around two semiconductor regions (e.g., two nanoribbons). Each nanoribbon component includes a G, S, and D, as described with respect to FIG. 2.

The gate terminals of the three nanoribbons within the two transistors 600a and 600b are coupled together and connected to a GL 630. One of the S/D terminals (in this example, the source terminal, S) of both transistors 600a and 600b (including the source ends of the two nanoribbons of transistor 600b) are coupled together (e.g., in a S/D region) and then coupled to a SL 610. In transistor 600a, the opposite S/D terminal (in this example, the drain terminal, D) is independent from the transistor 600b; the drain terminal D of transistor 600a is coupled to a first DL 620a. In transistor 600b, the two drain terminals D of the two nanoribbons are coupled together and connected to a second DL 620b, which is independent from DL 620a. By including two separate DLs 620a and 620b, the stack of semiconductor regions can be used to form two independent transistors.

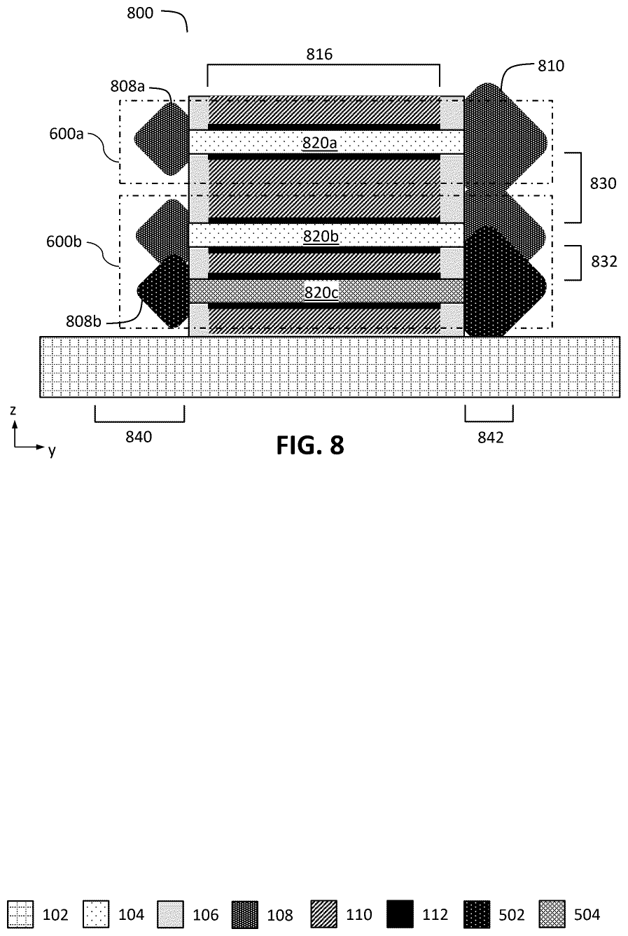

The transistors 600a and 600b illustrated in FIG. 6 may be realized in several different ways. Two example implementations are shown in FIGS. 7 and 8, and additional variations are described. While two transistors 600a and 600b are illustrated in FIG. 6, and stacks of two transistors illustrated in FIGS. 7 and 8, additional transistors (e.g., three, four, five, six, or more transistors) each formed around one or more semiconductor regions in a stack may be included; the additional transistors may be connected in a similar manner to the transistors 600 in FIG. 6. Furthermore, while one side of the transistors 600 is represented and described as a source and the other side represented and described as a drain, as noted above, designations of source and drain are often interchangeable, and the source and drain regions may be reversed (i.e., so that the sources are coupled together, and the drains are independent).

FIG. 7 is a cross-section of a first example implementation of a stack 700 of transistors with unequally spaced semiconductor regions. FIG. 7 depicts an example with smaller epitaxial deposits on the drain side. In FIG. 7, a stack of three semiconductor regions 720a, 720b, and 720c are over a support structure 102, which may be the support structure 102 described with respect to FIG. 1. The first transistor 600a is formed around the uppermost semiconductor region 720a, the second transistor 600b is formed around the middle semiconductor region 720b around the lowest semiconductor region 720c.

The semiconductor regions 720, also referred to herein as nanoribbons 720, include the channel material 104. The semiconductor regions 720 are generally similar to the semiconductor regions 120 and 420, described above. While a stack of three nanoribbons 720a-720c is shown, in other embodiments, the stack of nanoribbons may include more or fewer nanoribbons, e.g., two, four, five, six or more nanoribbons 720. Furthermore, in other embodiments, a different number of transistors with a different number of independent drains (e.g., three transistors, four transistors, five transistors, etc.) may be formed.

Each nanoribbon 720 is at a different height in the z-direction in the coordinate system shown, i.e., a different distance from the support structure 102, where the nanoribbon 720a is the greatest distance from the support structure 102, and the nanoribbon 720c is the smallest distance from the support structure 102. In this example, the nanoribbons 720 are unevenly spaced; a first distance 730 is between the nanoribbons 720a and 720b, and a second distance 732 is between the nanoribbons 720b and 720c. This spacing enables the formation of two independent transistors 600a and 600b, as described below. This spacing may be achieved by including a thicker layer of sacrificial material having the height 730 between nanoribbons 720a and 720b and a thinner layer of sacrificial material having the height 732 between nanoribbons 720b and 720c. In other embodiments, the nanoribbon 720b may be nearer to the nanoribbon 720a, so that the upper transistor includes two nanoribbons 720a and 720b, and the lower transistor includes one nanoribbon 720c.

Central portions of the nanoribbons 720a-720c are surrounded by a gate stack 716, which like the gate stacks 116, 416, and 516 includes a gate electrode 110 and gate dielectric 112 described with respect to FIG. 1. The gate dielectric 112 surrounds the nanoribbons 720, and the gate electrode 110 surrounds the gate dielectric 112. In this example, the gate dielectric 112 and gate electrode 110 span the heights 730 and 732 between pairs of adjacent nanoribbons 720, so that the gate electrode 110 electrically couples the nanoribbons 720a, 720b, and 720c. As in FIGS. 1 and 4, two regions of the dielectric material 106 are on either side of the gate stack 716, forming spacers similar to the cavity spacers 130 shown in FIG. 1 and described above. Other regions of the device outside of the nanoribbons 720, gate stack 716, and S/D regions 708 and 710 (described below) may also be filled in with a dielectric material, e.g., the dielectric material 106.

Two independent S/D regions 708a and 708b are at one end of the nanoribbons 720, e.g., the drain side. The upper S/D region 708a is physically and electrically coupled to the nanoribbon 720a. The lower S/D region 708b is physically and electrically coupled to the nanoribbons 720b and 720c; the lower S/D region 708b thus electrically couples the left ends or drain ends of the nanoribbons 720b and 720c together. The S/D regions 708a and 708b are physically and electrically isolated from each other. Thus, individual transistors 600a and 600b have their own independent drain regions 708a and 708b, respectively.

On the opposite end of the nanoribbons, e.g., the source side of the nanoribbons 720, an S/D region 710 is coupled to each of the nanoribbons 720a, 720b, and 720c. The S/D region 710 spans the height of the stack of nanoribbons 720 and is physically and electrically coupled to each of the nanoribbons 720a, 720b, and 720c, thus electrically coupling the right or source ends of the nanoribbons 720a, 720b, and 720c together. The S/D region 710 may be similar to the S/D region 108b of FIG. 1.

The S/D regions 708 and 710 may include the S/D materials 108 described with respect to FIG. 1. In the illustration of FIG. 7, the S/D regions 708 and 710 may be epitaxially grown. As described with respect to FIG. 4, epitaxial growth process can result in a generally diamond-shaped structure, as shown in FIG. 7, due to the crystallographic orientation of the underlying semiconductor material (e.g., the nanoribbons 720) and/or the growth process itself. Specifically, during an epitaxial deposition process, the growth tends to follow the crystal structure of the underlying structures, with a higher growth rate along certain crystallographic directions compared to others.

The S/D region 710 has a width 742 that is greater than a width 740 of the S/D regions 708a and 708b. To obtain the single S/D region 710 at one end of the nanoribbons 720 and the two independent S/D regions 708a and 708b on the opposite ends of the nanoribbons 720, separate deposition processes for the S/D regions 708 and 710 may be performed, or at least part of the epitaxial growth of the S/D region 710 may be grown while the drain ends of the nanoribbons 720 or epitaxial regions 708 are blocked, as described with respect to FIG. 4.

In FIG. 7, the channel material 104 is included in the three nanoribbons 720a, 720b, and 720c, and the S/D material 108 is included in the S/D regions 708 and 710. In other embodiments, different materials may be included at different rows in the nanoribbon stack. For example, the upper nanoribbon 720a may include a different channel material (e.g., the channel material 504, described above), and the S/D region 708a and upper portion of the S/D region 710 may include a different S/D material (e.g., the S/D material 502, described above). As another example, a single transistor (e.g., the transistor 600b) may include nanoribbons with different materials and/or an S/D region that includes two different materials.

FIG. 8 is a cross-section of a second example implementation of FIG. 6 with different materials in a single transistor, according to some embodiments of the present disclosure. FIG. 8 includes a stack 800 of the three transistors 600a, 600b, and 600c, formed around three nanoribbons 820a, 820b, and 820c. The nanoribbons 820 are similar to the nanoribbons 720 of FIG. 7, except that one nanoribbon, here 820c, has a different channel material 504 from the channel material 104 of the other nanoribbons 520b and 520c. The channel materials 104 and 504 may have, for example, different elements, element or material concentrations, material structures, and/or thicknesses as described with respect to FIG. 5. In the example of FIG. 8, nanoribbons 820a and 820b are separated by a distance 830, and nanoribbons 820b and 820c are separated by a distance 832.

The S/D regions 808 and 810 are similar to the S/D regions 708 and 710 of FIG. 7, except that a different S/D material 502 is coupled to the nanoribbon 820c. The S/D regions 808 have a width 840, which is similar to the width 740, and the S/D region 810 has a width 842, which is similar to the width 742. A gate stack 816, similar to the gate stack 716 of FIG. 7, surrounds the nanoribbons 820.

In this example, the lower portion of the S/D region 808b coupled to the left end of the nanoribbon 820c, and the lower portion of the S/D region 810 coupled to the right end of the nanoribbon 820c, are formed from a S/D material 502 that is different from the S/D material 108. The S/D materials 502 and 108 may have different physical properties, electrical properties, or deposition characteristics, as described above. The different S/D materials 108 and 502 may be grown in separate processes, as described with respect to FIG. 5. In the S/D region 808b and the S/D region 810, the respective portions of the S/D material 502 and the S/D material 108 are physically and electrically coupled, so that charge may pass from the S/D material 502 to the S/D material 108 or vice versa.

Using two different channel materials in different semiconductor regions of a single transistor can result in a transistor (e.g., the implementation of the transistor 600b shown in FIG. 8) that has two power modes. A lower threshold voltage may cause current to flow across a first semiconductor region or first set of semiconductor regions (e.g., the region comprising the channel material 104), while a higher threshold voltage may cause current to flow across one or more additional semiconductor regions (e.g., both the region comprising the channel material 104 and the region comprising the channel material 504).

### Example Nanoribbon Transistors with Independent Sources and Independent Drains

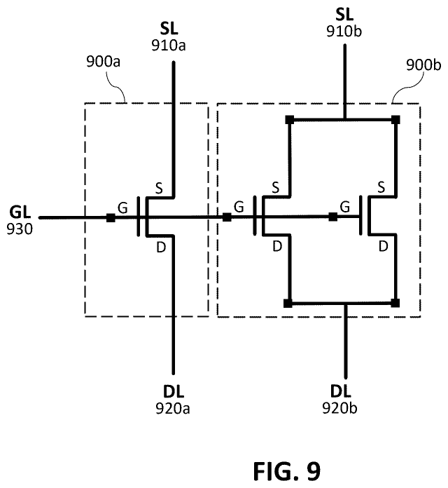

FIG. 9 is an electrical circuit diagram of a stack of nanoribbon-based transistors with two independent drain regions and two independent source regions, according to some embodiments of the present disclosure. FIG. 9 includes two transistors 900a and 900b, where transistor 900a is formed around a single semiconductor region, such as a nanoribbon, and transistor 900b is formed around two semiconductor regions (e.g., two nanoribbons). Each nanoribbon component includes a G, S, and D, as described with respect to FIG. 2.

The gate terminals of the three nanoribbons within the two transistors 900a and 900b are coupled together and connected to a single GL 930. The transistor 900a has a first independent SL 910a coupled to one end of the semiconductor region and a first independent DL 920a coupled to an opposite end of the semiconductor region. In the transistor 900b, two source terminals S of the two nanoribbons are coupled together and connected to a second independent SL 910b, which is independent from SL 910a. In addition, two drain terminals D of the two nanoribbons of transistor 900b are coupled together and connected to a second independent DL 920b, which is independent from DL 920a.

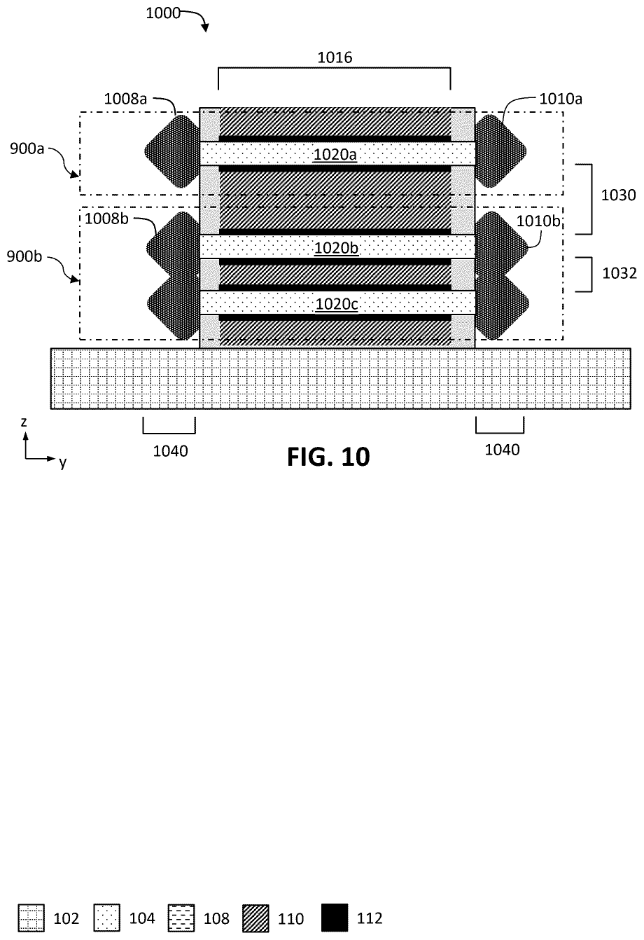

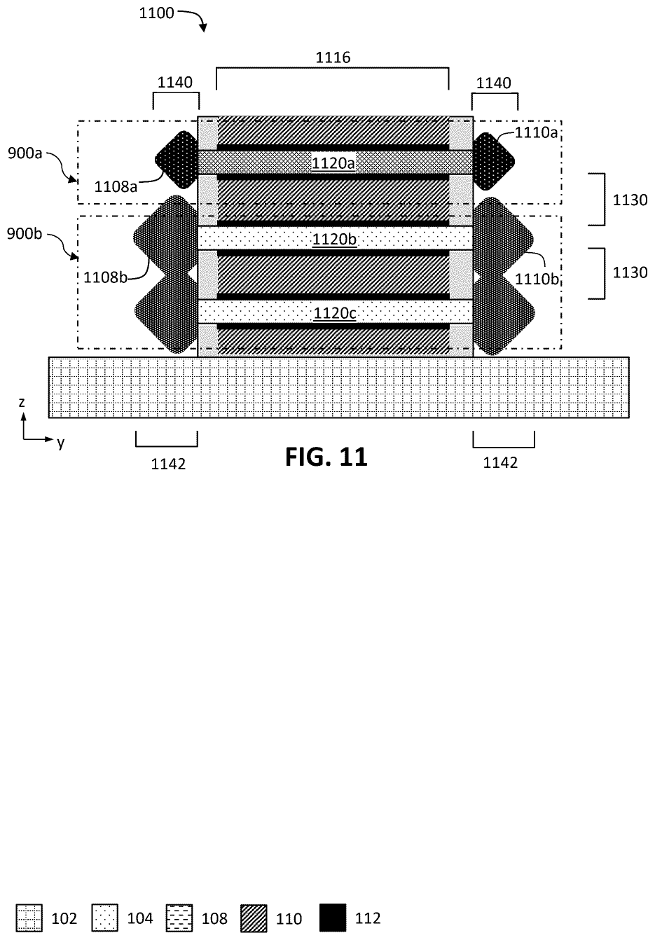

The transistors 900a and 900b illustrated in FIG. 9 may be realized in several different ways. Two example implementations are shown in FIGS. 10 and 11, and additional variations are described. While two transistors 900a and 900b are illustrated in FIG. 9, and stacks of two transistors illustrated in FIGS. 10 and 11, additional transistors (e.g., three, four, five, six, or more transistors) each formed around one or more semiconductor regions in a stack may be included; the additional transistors may be connected in a similar manner to the transistors 900 in FIG. 9.

FIG. 10 is a cross-section of a first example implementation of FIG. 9 that includes a stack 1000 of transistors 900 formed around unequally spaced semiconductor regions. FIG. 10 includes source and drain regions that may be formed in a single process and that, due to the unequal spacing of the semiconductor regions, result in a stack of two independent transistors. In FIG. 10, a stack of three semiconductor regions 1020a, 1020b, and 1020c are over a support structure 102, which may be the support structure 102 described with respect to FIG. 1. The first transistor 900a is formed around the uppermost semiconductor region 1020a, the second transistor 900b is formed around the middle semiconductor region 1020b around the lowest semiconductor region 1020c.

The semiconductor regions 1020, also referred to herein as nanoribbons 1020, include the channel material 104. The semiconductor regions 1020 are generally similar to the semiconductor regions 120 and 420, described above. While a stack of three nanoribbons 1020a-1020c is shown, in other embodiments, the stack of nanoribbons may include more or fewer nanoribbons, e.g., two, four, five, six or more nanoribbons 1020. Furthermore, in other embodiments, a different number of transistors with a different number of independent drains (e.g., three transistors, four transistors, five transistors, etc.) may be formed.

Each nanoribbon 1020 is at a different height in the z-direction in the coordinate system shown, i.e., a different distance from the support structure 102, where the nanoribbon 1020a is the greatest distance from the support structure 102, and the nanoribbon 1020c is the smallest distance from the support structure 102. In this example, the nanoribbons 1020 are unevenly spaced; a first distance 1030 is between the nanoribbons 1020a and 1020b, and a second distance 1032 is between the nanoribbons 1020b and 1020c. This spacing enables the formation of two independent transistors 900a and 900b, as described below. This spacing may be achieved by including a thicker layer of sacrificial material having the height 1030 between nanoribbons 1020a and 1020b and a thinner layer of sacrificial material having the height 1032 between nanoribbons 1020b and 1020c. In other embodiments, the nanoribbon 1020b may be nearer to the nanoribbon 1020a, so that the upper transistor includes two nanoribbons 1020a and 1020b, and the lower transistor includes one nanoribbon 1020c.

Central portions of the nanoribbons 1020a-1020c are surrounded by a gate stack 1016, which like the gate stacks 116, 416, 516, 716, and 816 includes a gate electrode 110 and gate dielectric 112 described with respect to FIG. 1. The gate dielectric 112 surrounds the nanoribbons 1020, and the gate electrode 110 surrounds the gate dielectric 112. In this example, the gate dielectric 112 and gate electrode 110 span the heights 1030 and 1032 between pairs of adjacent nanoribbons 1020, so that the gate electrode 110 electrically couples the nanoribbons 1020a, 1020b, and 1020c. As in prior figures, two regions of the dielectric material 106 are on either side of the gate stack 1016, forming spacers similar to the cavity spacers 130 shown in FIG. 1 and described above. Other regions of the device outside of the nanoribbons 1020, gate stack 1016, and S/D regions 1008 and 1010 (described below) may also be filled in with a dielectric material, e.g., the dielectric material 106.

Two independent S/D regions 1008a and 1008b are at one end of the nanoribbons 1020, e.g., the drain side. The upper S/D region 1008a is physically and electrically coupled to the nanoribbon 1020a. The lower S/D region 1008b is physically and electrically coupled to the nanoribbons 1020b and 1020c; the lower S/D region 1008b thus electrically couples the left ends or drain ends of the nanoribbons 1020b and 1020c together. The S/D regions 1008a and 1008b are physically and electrically isolated from each other. Thus, individual transistors 900a and 900b have their own independent drain regions 1008a and 1008b, respectively.

Two other independent S/D regions 1108a and 1108b are at the opposite end of the nanoribbons, e.g., the source side. The upper S/D region 1010a is physically and electrically coupled to the nanoribbon 1020a. The lower S/D region 1010b is physically and electrically coupled to the nanoribbons 1020b and 1020c; the lower S/D region 1010b thus electrically couples the right ends or source ends of the nanoribbons 1020b and 1020c together. The S/D regions 1010a and 1010b are physically and electrically isolated from each other. Thus, individual transistors 900a and 900b also have their own independent source regions 1010a and 1010b, respectively.

The S/D regions 1008 and 1010 may include the S/D materials 108 described with respect to FIG. 1. In the illustration of FIG. 10, the S/D regions 1008 and 710 may be epitaxially grown. As described with respect to FIG. 4, epitaxial growth process can result in a generally diamond-shaped structure, as shown in FIG. 10, due to the crystallographic orientation of the underlying semiconductor material (e.g., the nanoribbons 1020) and/or the growth process itself. Specifically, during an epitaxial deposition process, the growth tends to follow the crystal structure of the underlying structures, with a higher growth rate along certain crystallographic directions compared to others.

The S/D regions 1008 and 1010 each have a width 1040. The S/D regions 1008a, 1008b, 1010a, and 1010b may be grown in a single deposition process. The relative spacing between the nanoribbons 1020 (e.g., the larger distance 1030 between the transistors 900a and 900b than between the nanoribbons 1020b and 1020c) results in the S/D arrangement shown in FIG. 10.

In FIG. 10, the channel material 104 is included in the three nanoribbons 1020a, 1020b, and 1020c, and the S/D material 108 is included in the S/D regions 1008 and 1010. In other embodiments, different materials may be included at different rows in the nanoribbon stack. For example, the upper nanoribbon 1020a may include a different channel material (e.g., the channel material 504, described above), and the S/D regions 1008a and/or 1010b may include a different S/D material (e.g., the S/D material 502, described above). As another example, a single transistor (e.g., the transistor 900b) may include nanoribbons with different materials and/or an S/D region that includes two different materials, as described with respect to FIG. 8.

FIG. 11 is a cross-section of a second example implementation of FIG. 9 with different materials in different transistors, according to some embodiments of the present disclosure. In addition, while in FIG. 10, the nanoribbons 1020 were unevenly spaced, in FIG. 11, nanoribbons are evenly spaced.

FIG. 11 includes a stack 1100 of the three transistors 900a, 900b, and 900c, formed around three nanoribbons 1120a, 1120b, and 1120c. The nanoribbons 1120 are generally similar to nanoribbons described above. Compared to the nanoribbons 1020 of FIG. 10, here, one nanoribbon, 1120a, has a different channel material 504 from the channel material 104 of the other nanoribbons 1120b and 1120c. The channel materials 104 and 504 may have, for example, different elements, element or material concentrations, material structures, and/or thicknesses as described with respect to FIG. 5. In addition, in the example of FIG. 11, nanoribbons 1120a and 1120b are separated by a distance 1130, and nanoribbons 1120b and 1120c are separated by the same distance 1130, or substantially the same difference, as described with respect to FIG. 4. A gate stack 1116, similar to the gate stack 1016 of FIG. 10, surrounds the nanoribbons 1120.

The S/D regions 1108b and 1110b are similar to the S/D regions 1108b and 1110b of FIG. 10. The S/D regions 1108b and 1110b have a width 1142. The S/D regions 1108a and 1110a coupled to the nanoribbon 1120a include a different S/D material 502 from the S/D regions 1108b and 1110b. The S/D materials 502 and 108 may have different physical properties, electrical properties, or deposition characteristics, as described above. The S/D regions 1108a and 1110a have a width 1140, which is smaller than the width 1142. Because the nanoribbons 1120 are evenly spaced, the larger width 1142 of the S/D regions 1108b and 1110b allows the epitaxial deposits to form a single S/D region on each side (i.e., coupling the source ends and drain ends of the nanoribbons 1120b and 1120c), while the smaller width 1140 of the S/D regions 1108a and 1110a keeps these 1108a and 1110a physically and electrically separated from the S/D regions 1108b and 1110b and prevents the S/D regions 1108a and 1110a from shorting with the S/D regions 1108b and 1110b. The S/D regions 1108b and 1110b of transistor 900b may be formed in a different deposition process from the S/D regions 1108a and 1110a of transistor 900a.

### Example Nanoribbon Transistors with Independent Gates and Independent Drains

As noted above, in addition to having independent sources or drains, a stack of transistors may also have independent gates. For example, a first nanoribbon or first set of nanoribbons may be coupled to a first S/D region at one end, and have a first gate stack surrounding a center portion of the nanoribbon(s). A second nanoribbon or second set of nanoribbons may be coupled to a second S/D region at one end, where the second S/D region is physically and electrically separated from the first S/D region. The second nanoribbon(s) can further have a second gate stack surrounding a center portion of the nanoribbon(s), where the second gate stack is physically and electrically separated from the first gate stack.

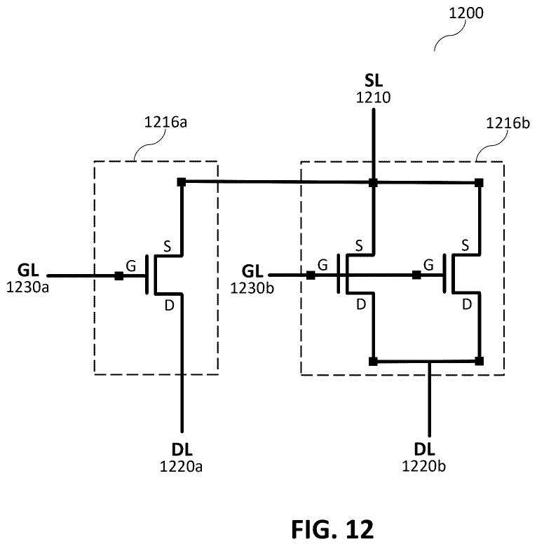

FIG. 12 is an electrical circuit diagram of a stack of nanoribbon-based transistors with two independent drain regions and two independent gate stacks, according to some embodiments of the present disclosure. FIG. 12 includes two transistors 1200a and 1200b, where transistor 1200a is formed around a single semiconductor region, such as a nanoribbon, and transistor 1200b is formed around two semiconductor regions (e.g., two nanoribbons). Each nanoribbon component includes a G, S, and D, as described with respect to FIG. 2.

One of the S/D terminals (in this example, the source terminal, S) of both transistors 1200a and 1200b (including the source ends of the two nanoribbons of transistor 1200b) are coupled together (e.g., in an S/D region) and then coupled to a SL 1210. In transistor 1200a, the opposite S/D terminal (in this example, the drain terminal, D) is independent from the transistor 1200b; the drain terminal D of transistor 1200a is coupled to a first DL 1220a. In transistor 1200b, the two drain terminals D of the two nanoribbons are coupled together and connected to a second DL 1220b, which is independent from DL 1220a.

In transistor 1200a, the gate terminal G is coupled to a first GL 1230a. In transistor 1200b, the two gate terminals G of the two nanoribbons are coupled together (e.g., by a single gate electrode) and connected to a second GL 1230b, which is independent from GL 1230a. By including two separate DLs 1220a and 1220b and two separate GLs 1230a and 1230b, the stack of semiconductor regions can be used to form two independent transistors.

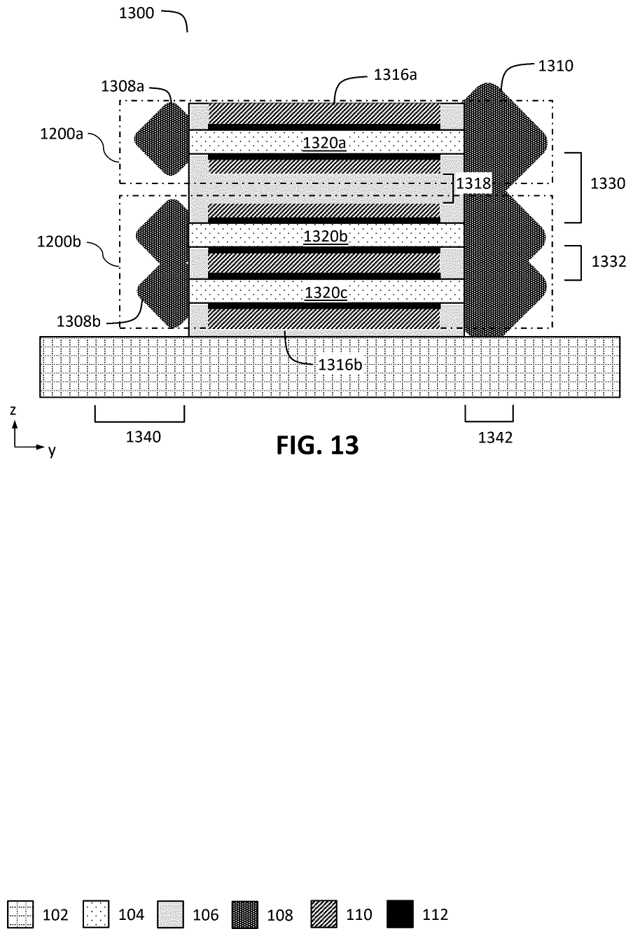

The transistors 1200a and 1200b illustrated in FIG. 12 may be realized in several different ways. For example, in any of the example implementations shown above, separate gate stacks may be provided for the different transistors. One example implementation is shown in FIG. 13. FIG. 13 includes an unevenly space stack of nanoribbons, but in other embodiments, two or more independent gate stacks may be formed around stacks of evenly spaced nanoribbons; two or more different sacrificial materials may be used and arranged between the nanoribbons to form the gate stacks in separate deposition processes. While two transistors 1200a and 1200b are illustrated in FIG. 12, and stacks of two transistors illustrated in FIGS. 12 and 13, additional transistors (e.g., three, four, five, six, or more transistors) each formed around one or more semiconductor regions in a stack may be included; the additional transistors may be connected in a similar manner to the transistors 1200 in FIG. 12.

FIG. 13 is a cross-section of one example implementation of FIG. 12, according to some embodiments of the present disclosure. FIG. 13 depicts an example with smaller epitaxial deposits on the drain side and unevenly spaced nanoribbons. In FIG. 13, a stack of three semiconductor regions 1320a, 1320b, and 1320c are over a support structure 102, which may be the support structure 102 described with respect to FIG. 1. The first transistor 1200a is formed around the uppermost semiconductor region 1320a, the second transistor 1200b is formed around the middle semiconductor region 1320b around the lowest semiconductor region 1320c.

The semiconductor regions 1320 are similar to the semiconductor regions 720 of FIG. 7, described above. While a stack of three nanoribbons 1320a-1320c is shown, in other embodiments, the stack of nanoribbons may include more or fewer nanoribbons, and may form a different number of transistors with a different number of independent drains and independent sources. As in FIG. 7, each nanoribbon 1320 is at a different height in the z-direction in the coordinate system shown. A first distance 1330, similar to the distance 730, is between the nanoribbons 1320a and 1320b, and a second distance 1332, similar to the distance 732, is between the nanoribbons 1320b and 1320c. In other embodiments, the nanoribbon 1320b may be nearer to the nanoribbon 1320a, so that the upper transistor includes two nanoribbons 1320a and 1320b, and the lower transistor includes one nanoribbon 1320c.

A central portion of the nanoribbon 1320a is surrounded by a first gate stack 1316a, and central portions of the nanoribbons 1320b and 1320c are surrounded by a second gate stack 1316b. The gate stacks 1316 include a gate electrode 110 and gate dielectric 112 described with respect to FIG. 1. The gate dielectric 112 surrounds each nanoribbon 1320, and the gate electrode 110 surrounds the gate dielectric 112. In this example, the gate dielectric 112 and gate electrode 110 does not span the height 1330 between nanoribbons 1320a and 1320b, and instead, a dielectric region 1318 is between the two gate stacks 1316a and 1316b. In addition, as in prior figures, two regions of the dielectric material 106 are on either side of the gate stacks 1316, forming spacers similar to the cavity spacers 130 shown in FIG. 1 and described above. While the dielectric region 1318 and the cavity spacers are shown as including the same dielectric material 106, different dielectric materials may be used. Other regions of the device outside of the nanoribbons 1320, gate stacks 1316, and S/D regions 1308 and 1310 may also be filled in with a dielectric material, e.g., the dielectric material 106.

Two independent S/D regions 1308a and 1308b are at one end of the nanoribbons 1320, e.g., the drain side. The S/D regions 1308a and 1308b are similar to the S/D regions 708 of FIG. 7, described above. On the opposite end of the nanoribbons, e.g., the source side of the nanoribbons 1320, an S/D region 1310 is coupled to each of the nanoribbons 1320a, 1320b, and 1320c. The S/D region 1310 is similar to the S/D region 710, described above. As in FIG. 7, the S/D region 1310 has a width 1342 that is greater than a width 1340 of the S/D regions 1308a and 1308b.

While FIG. 13 illustrates a single channel material, a single S/D material, a single gate dielectric 112, and a single gate electrode 110, in other embodiments, different transistors, or different nanoribbons of the same transistor, may include different materials, e.g., as shown in FIGS. 5, 8, and 11.

### Example Devices

The circuit devices with stacked transistors with independent sources or drains disclosed herein may be included in any suitable electronic device. FIGS. 14-18 illustrate various examples of apparatuses that may include the one or more transistors or memory cells disclosed herein, which may have been fabricated using the processes disclosed herein.

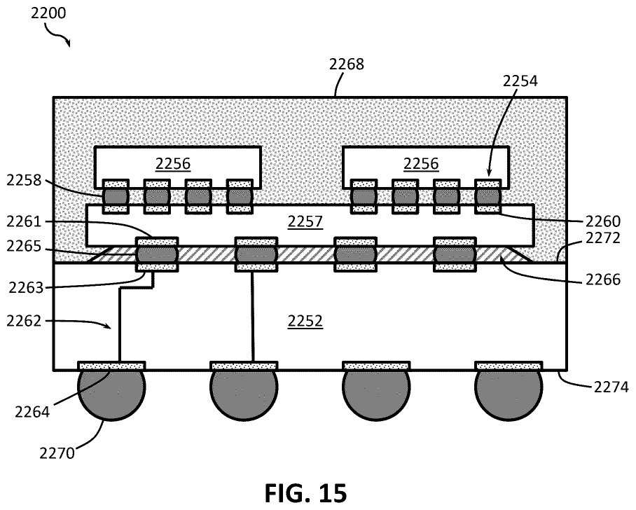

FIG. 14 illustrates top views of a wafer 2000 and dies 2002 that may include one or more stacked transistors with independent sources or drains in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 15. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more stacked transistors with independent sources or drains as described herein). After the fabrication of the semiconductor product is complete (e.g., after manufacture of any embodiment of the IC device 100 as described herein), the wafer 2000 may undergo a singulation process in which each of the dies 2002 is separated from one another to provide discrete “chips” of the semiconductor product. In particular, devices that include one or more stacked transistors with independent sources or drains as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a hysteretic memory device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 15) or other logic that is configured to store information in the memory devices or execute instructions stored in the memory array.

FIG. 15 is a side, cross-sectional view of an example IC package 2200 that may include one or more stacked transistors with independent sources or drains in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 15 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 15 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

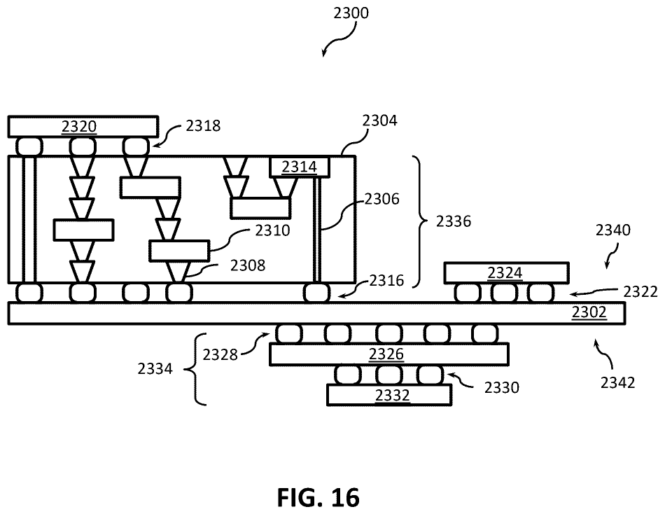

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 15 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 16.

The dies 2256 may take the form of any of the embodiments of the die 2002 discussed herein (e.g., may include any of the embodiments of the IC devices with one or more stacked transistors with independent sources or drains as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices with one or more stacked transistors with independent sources or drains, e.g., as discussed above; in some embodiments, at least some of the dies 2256 may not include any stacked transistors with independent sources or drains.

The IC package 2200 illustrated in FIG. 15 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 15, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 16 is a cross-sectional side view of an IC device assembly 2300 that may include components having one or more stacked transistors with independent sources or drains in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more stacked transistors with independent sources or drains in accordance with any of the embodiments disclosed herein; e.g., any of the IC packages discussed below with reference to the IC device assembly 2300 may take the form of any of the embodiments of the IC package 2200 discussed above with reference to FIG. 15 (e.g., may include one or more stacked transistors with independent sources or drains provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 16 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 16), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 14), an IC device, or any other suitable component. In particular, the IC package 2320 may include one or more stacked transistors with independent sources or drains as described herein. Although a single IC package 2320 is shown in FIG. 16, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 16, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 16 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

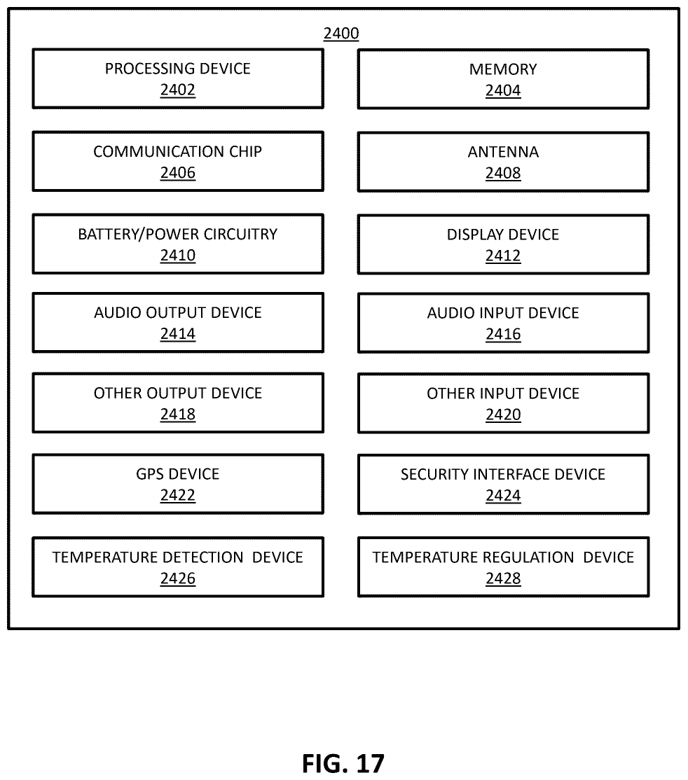

FIG. 17 is a block diagram of an example computing device 2400 that may include one or more components including one or more IC devices with one or more stacked transistors with independent sources or drains in accordance with any of the embodiments disclosed herein. For example, any suitable ones of the components of the computing device 2400 may include a die (e.g., the die 2002 of FIG. 14) having one or more stacked transistors with independent sources or drains as described herein. Any one or more of the components of the computing device 2400 may include, or be included in, an IC package 2200 of FIG. 15 or an IC device 2300 of FIG. 16.

A number of components are illustrated in FIG. 17 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 17, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

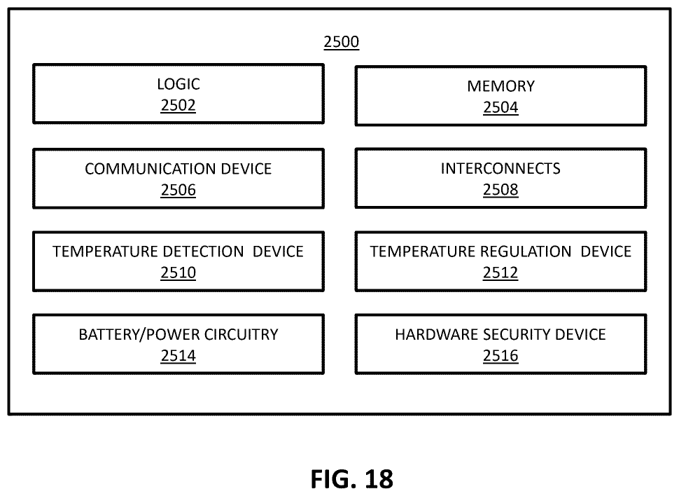

FIG. 18 is a block diagram of an example processing device 2500 that may include one or more IC devices with one or more stacked transistors with independent sources or drains in accordance with any of the embodiments disclosed herein. For example, any suitable ones of the components of the processing device 2500 may include a die (e.g., the die 2002 of FIG. 14) having one or more stacked transistors with independent sources or drains as described herein. Any one or more of the components of the processing device 2500 may include, or be included in, an IC device 1400 (FIG. 16). Any one or more of the components of the processing device 2500 may include, or be included in, an IC package 2200 of FIG. 15 or an IC device 2300 of FIG. 16. Any one or more of the components of the processing device 2500 may include, or be included in, a computing device 2400 of FIG. 17; for example, the processing device 2500 may be the processing device 2402 of the computing device 2400.

A number of components are illustrated in FIG. 18 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 18, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 17). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 17). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 17 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 17 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 17. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 17. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### Select Examples

The following paragraphs provide various examples of the embodiments disclosed herein.
Example 1 provides a device including a plurality of semiconductor regions arranged in a stack, each of the plurality of semiconductor regions having a first end and a second end; a first source or drain region coupled to a first of the plurality of semiconductor regions at the first end of the first semiconductor region; a second source or drain region coupled to a second and a third of the plurality of semiconductor regions at the first end of the second semiconductor region and the first end of the second semiconductor region; where the first semiconductor region is adjacent to the second semiconductor region in the stack, and a first distance between the first and second semiconductor regions is greater than a second distance between the second and third semiconductor regions.
Example 2 provides the device of example 1, where the first source or drain region is coupled to the first semiconductor region and not to any other semiconductor region in the stack.
Example 3 provides the device of example 1, where the first source or drain region is coupled to an odd number of semiconductor regions.
Example 4 provides the device of example 1, where the first source or drain region is coupled to a different number of semiconductor regions from the second source or drain region.
Example 5 provides the device of any preceding example, further including a gate coupled to the first semiconductor region, the second semiconductor region, and the third semiconductor region.
Example 6 provides the device of any preceding example, further including a third source or drain region coupled to the first semiconductor region at the second end of the first semiconductor region.
Example 7 provides the device of example 6, where the third source or drain region is further coupled to the second semiconductor region at the second end of the second semiconductor region.
Example 8 provides the device of example 7, where the third source or drain region is further coupled to the third semiconductor region at the second end of the third semiconductor region.
Example 9 provides the device of example 6, further including a fourth source or drain region coupled to the second semiconductor region at the second end of the second semiconductor region.
Example 10 provides the device of any preceding example, where the first semiconductor region and the second semiconductor region include different materials.
Example 11 provides the device of any preceding example, where the first source or drain region and the second source or drain region include different materials.
Example 12 provides a device including a plurality of nanoribbons arranged in a stack, each of the plurality of nanoribbons having a first end and a second end, where a first distance between a first pair of adjacent nanoribbons is substantially the same as a second distance between a second pair of adjacent nanoribbons; a first epitaxial region coupled to a first of the plurality of nanoribbons at the first end of the first nanoribbon; a second epitaxial region coupled to a second of the plurality of nanoribbons at the first end of the second nanoribbon; and a third epitaxial region coupled to the first and the second of the plurality of nanoribbons at the second end of the first nanoribbon and the second end of the second nanoribbon.
Example 13 provides the device of example 12, further including a gate region coupled to the first nanoribbon and the second nanoribbon.
Example 14 provides the device of example 13, where the gate region is between the first epitaxial region and the third epitaxial region.
Example 15 provides the device of any of examples 12-14, where the first nanoribbon and second nanoribbon extend parallel to each other in a first direction, and the first epitaxial region has a first width in the first direction, and the third epitaxial region has a second width in the first direction, the second width greater than the first width.
Example 16 provides the device of any of examples 12-15, where the third epitaxial region is a first source or drain for a first transistor including the first nanoribbon and for a second transistor including the first nanoribbon.
Example 17 provides the device of example 16, where the first epitaxial region is a second source or drain for the first transistor including the first nanoribbon.
Example 18 provides the device of example 17, where the second epitaxial region is a third source or drain for the second transistor including the second nanoribbon, where the second source or drain and third source or drain are independently controlled.
Example 19 provides an assembly including a circuit board; and an integrated circuit (IC) device coupled to the circuit board, the IC device including at least one stack of transistors, the stack of transistors including a plurality of semiconductor regions arranged in a stack, each of the plurality of semiconductor regions having a first end and a second end, where at least one semiconductor region includes a different material from at least one other semiconductor region; a first source or drain region coupled to a first semiconductor region in the stack at the first end of the first semiconductor region; a second source or drain region coupled to a second semiconductor region in the stack at the first end of the second semiconductor region; and a third source or drain region coupled to the first semiconductor region and the second semiconductor region at the second ends of the first semiconductor region and the second semiconductor region.
Example 20 provides the assembly of example 19, where the first semiconductor region has a different material composition from the second semiconductor region, and, in some embodiments, where the first source or drain region is further coupled to a third semiconductor region in the stack at the first end of the third semiconductor region, and the third semiconductor region has a different material composition from the first semiconductor region.
Example 21 provides an IC package that includes an IC die, including one or more of the IC devices according to any one of the preceding examples. The IC package may also include a further component, coupled to the IC die.
Example 22 provides the IC package according to example 21, where the further component is one of a package substrate, a flexible substrate, or an interposer.
Example 23 provides the IC package according to examples 21 or 22, where the further component is coupled to the IC die via one or more first level interconnects.
Example 24 provides the IC package according to example 23, where the one or more first level interconnects include one or more solder bumps, solder posts, or bond wires.
Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).
Example 26 provides the computing device according to example 25, where the computing device is a wearable computing device (e.g., a smart watch) or hand-held computing device (e.g., a mobile phone).
Example 27 provides the computing device according to examples 25 or 26, where the computing device is a server processor.
Example 28 provides the computing device according to examples 25 or 26, where the computing device is a motherboard.
Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a plurality of semiconductor regions arranged in a stack, each of the plurality of semiconductor regions having a first end and a second end;
a first source or drain region coupled to a first of the plurality of semiconductor regions at the first end of the first semiconductor region;
a second source or drain region coupled to a second and a third of the plurality of semiconductor regions at the first end of the second semiconductor region and the first end of the second semiconductor region;
wherein the first semiconductor region is adjacent to the second semiconductor region in the stack, and a first distance between the first and second semiconductor regions is greater than a second distance between the second and third semiconductor regions.

2. The device of claim 1, wherein the first source or drain region is coupled to the first semiconductor region and not to any other semiconductor region in the stack.

3. The device of claim 1, wherein the first source or drain region is coupled to an odd number of semiconductor regions.

4. The device of claim 1, wherein the first source or drain region is coupled to a different number of semiconductor regions from the second source or drain region.

5. The device of claim 1, further comprising a gate coupled to the first semiconductor region, the second semiconductor region, and the third semiconductor region.

6. The device of claim 1, further comprising a third source or drain region coupled to the first semiconductor region at the second end of the first semiconductor region.

7. The device of claim 6, wherein the third source or drain region is further coupled to the second semiconductor region at the second end of the second semiconductor region.

8. The device of claim 7, wherein the third source or drain region is further coupled to the third semiconductor region at the second end of the third semiconductor region.

9. The device of claim 6, further comprising a fourth source or drain region coupled to the second semiconductor region at the second end of the second semiconductor region.

10. The device of claim 1, wherein the first semiconductor region and the second semiconductor region comprise different materials.

11. The device of claim 1, wherein the first source or drain region and the second source or drain region comprise different materials.

12. A device comprising:
a plurality of nanoribbons arranged in a stack, each of the plurality of nanoribbons having a first end and a second end, wherein a first distance between a first pair of adjacent nanoribbons is substantially a same as a second distance between a second pair of adjacent nanoribbons;
a first epitaxial region coupled to a first of the plurality of nanoribbons at the first end of the first nanoribbon;
a second epitaxial region coupled to a second of the plurality of nanoribbons at the first end of the second nanoribbon; and
a third epitaxial region coupled to the first and the second of the plurality of nanoribbons at the second end of the first nanoribbon and the second end of the second nanoribbon.

13. The device of claim 12, further comprising a gate region coupled to the first nanoribbon and the second nanoribbon.

14. The device of claim 13, wherein the gate region is between the first epitaxial region and the third epitaxial region.

15. The device of claim 12, wherein the first nanoribbon and second nanoribbon extend parallel to each other in a first direction, and the first epitaxial region has a first width in the first direction, and the third epitaxial region has a second width in the first direction, the second width greater than the first width.

16. The device of claim 12, wherein the third epitaxial region is a first source or drain for a first transistor comprising the first nanoribbon and for a second transistor comprising the first nanoribbon.

17. The device of claim 16, wherein the first epitaxial region is a second source or drain for the first transistor comprising the first nanoribbon.

18. The device of claim 17, wherein the second epitaxial region is a third source or drain for the second transistor comprising the second nanoribbon, wherein the second source or drain and third source or drain are independently controlled.

19. An assembly comprising:
a circuit board; and
an integrated circuit (IC) device coupled to the circuit board, the IC device comprising at least one stack of transistors, the stack of transistors comprising:
a plurality of semiconductor regions arranged in a stack, each of the plurality of semiconductor regions having a first end and a second end, wherein at least one semiconductor region comprises a different material from at least one other semiconductor region;
a first source or drain region coupled to a first semiconductor region in the stack at the first end of the first semiconductor region;
a second source or drain region coupled to a second semiconductor region in the stack at the first end of the second semiconductor region; and
a third source or drain region coupled to the first semiconductor region and the second semiconductor region at the second ends of the first semiconductor region and the second semiconductor region.

20. The assembly of claim 19, wherein the first semiconductor region has a different material composition from the second semiconductor region.
